(19) United States
(12) Patent Application Publication
(10) Pub. No.: US 2017/0331016 A1
(43) Pub. Date: Nov. 16, 2017

(54) A LIGHTING DEVICE HAVING AN OPTICAL LENS FORMED ON COMPOSITE ENCAPSULANT COMPRISING NANOPARTICLES COVERING A LIGHT-EMITTING DIODE (LED)

(71) Applicants: Maxim Tchoul, Winchester, MA (US); Alan Lenef, Belmont, MA (US); Darshan Kundaliya, Beverly, MA (US)

(72) Inventors: Maxim Tchoul, Winchester, MA (US); Alan Lenef, Belmont, MA (US); Darshan Kundaliya, Beverly, MA (US)

(21) Appl. No.: 15/154,576

(22) Filed: May 13, 2016

(51) Int. Cl. H01L 33/54; H01L 33/58; H01L 33/50; H01L 33/56

(52) U.S. Cl. CPC H01L 33/54; H01L 33/56; H01L 33/58; H01L 33/507; H01L 2933/005; H01L 2933/0058; H01L 2933/0041

(57) ABSTRACT

There is herein described a lighting device including a composite encapsulant and an optical component. The lighting devices include a first interface between the composite encapsulant and a light emitting surface of a light source, and a second interface between the composite encapsulant and the optical component. In various embodiments, the composite encapsulant is configured to increase a critical angle at the first interface, so as to limit total internal reflection at the first interface. Moreover, the properties and/or other features of the composite encapsulant may be controlled to also limit total internal reflection at the second interface. Methods of making such lighting devices are also disclosed.

### FIELD

The present disclosure generally relates to lighting devices, including but not limited to lighting devices including one or a plurality of light emitting diodes. More particularly, the present disclosure relates to lighting devices that include a light source, a composite encapsulant layer, and an optical component, as well as methods of making the same.

### BACKGROUND

Solid state lighting devices are becoming increasingly common in the marketplace due to their relatively high power efficiency. One popular type of solid state lighting device is the light emitting diode, or LED. In general, the term LED refers to a wide variety of diode or other semiconductor-based devices that are capable of generating radiation (i.e., light) in response to an electrical signal. More particularly, LEDs are configured to generate light in one or more regions of the electromagnetic spectrum, such as the visible, ultraviolet, and/or infrared regions. In many instances, solid state light sources such as LEDs are configured such at least a portion of the light they produce is emitted from a surface thereof. For the sake of clarity, that surface is referred to herein as a “light emitting surface,” or simply “emitting surface,” though it should be understood that light from the light source may not originate from (i.e., emit) from the emitting surface per se.

Although solid state light sources such as LEDs can be relatively power efficient when compared to other types of light sources, various technical challenges exist which may limit the total amount of light that is emitted by an LED into its surrounding environment. For example, many LEDs are configured such that there is an interface between a light emitting surface thereof and an external medium (e.g., air, a polymer, etc.). The ratio of the refractive index (N1) of the material forming the light emitting surface of the LED and the refractive index (N2) of the external medium (e.g., air) may define a “critical angle” that can impact the amount of light that is emitted from the LED into the surrounding environment. More specifically, as the value of N2/N1 decreases the critical angle generally decreases, and vice versa. When light produced by an LED approaches an interface between the light emitting surface thereof and an external medium at an angle greater than the critical angle, total internal reflection may cause that light to be reflected back towards the LED, which may limit the amount of light output from the LED. This same consideration is true with regard other interfaces that may be present in a lighting device, i.e., where light propagating through a first medium having a first refractive index (N1) encounters an interface between the first medium and a second medium having a second refractive index (N2).

With the foregoing in mind, many LEDs include a light emitting surface that is formed from one or more high refractive index (HRI) materials. For example, some LEDs include a light emitting surface formed from gallium nitride (GaN) or aluminum gallium indium phosphide (AlGaInP), which exhibit refractive indices ranging from 2.3-2.5 (GaN) and 3.2-4.5 (AlGaInP), respectively. Therefore when a light emitting surface of such LEDs is in contact with air (N2=1.0 at standard temperature and pressure), the ratio of N2/N1 will be relatively low, resulting in a correspondingly low critical angle. Due to the relatively low critical angle, a significant amount of light produced by the LED may be totally internally reflected at the emitting surface/air interface, which in turn may limit the amount of light (i.e., luminous flux) that is ultimately emitted into the surrounding environment by the LED.

Research has shown that covering or encapsulating a light emitting surface of an LED with a polymeric material (hereinafter, an “encapsulant”) can increase the ratio of N2/N1, resulting in a corresponding increase in the critical angle and improved light extraction relative to light sources that include a light emitting surface/air interface. That increase in light extraction is largely attributable to the fact that such polymers exhibit a refractive index that is greater than that of air. As a result, the critical angle at the emitting surface/encapsulant interface may be larger than the critical angle at an emitting surface/air interface.

However, many encapsulants are formed from polymers that exhibit a refractive index (N1) that is still significantly lower than the refractive index (N2) of the light emitting surface of an LED. For example, in many applications a silicone or epoxy is used as an encapsulant for an LED. Such materials often exhibit a refractive index (N1) of 1.4 -1.6, which may still be significantly less than the refractive index (N2) of the materials used to form the light emitting surface of an LED. A significant amount of light produced by the LEDs in such devices may therefore still be lost due to total internal reflection at the light emitting surface/encapsulant interface.

### BRIEF DESCRIPTION OF THE DRAWINGS

Reference is now made to the following detailed description which should be read in conjunction with the following figures, wherein like numerals represent like parts:

FIG. 1A illustrates one example of a lighting device consistent with the present disclosure.

FIG. 1B illustrates another example of a lighting device consistent with the present disclosure.

FIG. 2 is a plot of simulated transmitted power vs. particle size of a hypothetical composite encapsulant including example high refractive index particles consistent with the present disclosure.

FIG. 3A is a plot of composite refractive index vs. weight percent of high refractive index particles for several example composite encapsulants consistent with the present disclosure.

FIG. 3B is a plot of refractive index vs. wavelength for several example composite encapsulants consistent with the present disclosure.

FIG. 4 is a flow chart depicting example operations of a method of making a lighting device including a composite encapsulant and an optical component consistent with the present disclosure.

### DETAILED DESCRIPTION

The present disclosure will now proceed with reference to the accompanying drawings, in which example embodiments consistent with the present disclosure are shown. It should be understood that the examples in the figures are for the sake of illustration and ease of understanding only and that the methods, wavelength converters, and devices described herein may be embodied in many forms and are not limited to the illustrated embodiments in the FIGS. or specific embodiments described herein.

One or more elements of the present disclosure may be numerically designated, e.g., as a first, second, third, etc. element. In this context it should be understood that the numerical designation is for the sake of clarity only (e.g., to distinguish one element from another), and that elements so designated are not limited by their specific numerical designation. Moreover the specification may from time to time refer to a first element may be described as being “on” a second element. In that context it should be understood that the first element may be directly on the second element (i.e., without intervening elements there between), or that one or more intervening elements may be present between the first and second elements. In contrast, the term “directly on” means that the first element is present on the second element without any intervening elements there between.

As used herein singular expressions such as “a,” “an,” and “the” are not limited to their singular form, and are intended to cover the plural forms as well unless the context clearly indicates otherwise. Specific terms/phrases excepted from this understanding include “single layer,” and “single layer wavelength converter,” which are used herein to designate a single (i.e., one) layer and a wavelength converter that is made up of a single (i.e. one) layer. As will be described in detail below non-limiting examples of single layer wavelength conversion materials consistent with the present disclosure include a single layer of matrix material including wavelength converting particles, such as but not limited to a combination of phosphor particles and quantum dot particles. This is in contrast to multilayer wavelength converters, in which several layers of different wavelength converting compositions are stacked on or otherwise aligned with one another.

As used herein, the terms “substantially” and “about” when used in connection with an amount or range mean plus or minus 5% of the stated amount or the endpoints of the stated range.

As used herein, the term “on” may be used to describe the relative position of one component (e.g., a first layer) relative to another component (e.g., a second layer). In such instances the term “on” should be understood to indicate that a first component is present above a second component, but is not necessarily in contact with one or more surfaces of the second component. That is, when a first component is “on” a second component, one or more intervening components may be present between the first and second components. In contrast, the term “directly on” should be interpreted to mean that a first component is in contact with a surface (e.g., an upper surface) or a second component. Therefore when a first component is “directly on” a second component, it should be understood that the first component is in contact with the second component, and that no intervening components are present between the first and second components.

As used herein, the term “optically transparent” when used in connection with a material (e.g., a matrix of an composite encapsulant, a filler, etc.) means that the referenced material transmits greater than or equal to about 80% of incident light, such as greater than or equal to about 90%, greater than or equal to about 95%, greater than or equal to about 99%, or even about 100% of incident light. The incident light may be of a specified wavelength or wavelength range (e.g., ultraviolet, visible, infrared, etc.), or may span multiple wavelength ranges. Without limitation, materials described herein as being optically transparent preferably transmit greater than or equal to about 95% (e.g., greater than or equal to about 99% or even about 100%) of incident light in at least one of the ultraviolet, visible, and infrared regions of the electromagnetic spectrum.

As used herein, the terms, “light emitting diode,”“LED,” and “LED light source” are used interchangeably, and refer to any light emitting diode or other type of semiconductor-based system that is capable of generating radiation in response to an electrical signal. Thus, the term LED includes, but is not limited to, various semiconductor-based structures that emit light in response to current, light emitting polymers, light emitting strips, electro-luminescent strips, combination thereof and the like. In particular, the term LED refers to light emitting diodes of all types that may be configured to generate light in all or various portions of one or more of the visible, ultraviolet, and infrared spectrum. Non-limiting examples of suitable LEDs that may be used include various types of infrared LEDs, ultraviolet LEDs, red LEDs, green LEDs, blue LEDs, yellow LEDs, amber LEDs, orange LEDs, and white LEDs. Such LEDs may be configured to emit light over a broad spectrum (e.g., the entire visible light spectrum) or a narrow spectrum. References to the color of a phosphor, LED or conversion material refer generally to its emission color unless otherwise specified. Thus, a blue LED emits a blue light, a yellow phosphor emits a yellow light and so on.

From time to time one or more aspects of the present disclosure may be described using ranges. In such instances it should be understood that the indicated ranges are exemplary only unless expressly indicated otherwise. Moreover, the indicated ranges should be understood to include all of the individual values of falling within the indicated range, as though such values were expressly recited. Moreover, the ranges should be understood to encompass sub ranges within the indicated range, as though such sub ranges were expressly recited. By way of example, a range of 1 to 10 should be understood to include 2, 3, 4 . . . etc., as well as the range of 2 to 10, 3 to 10, 2 to 8, etc., as though such values and ranges were expressly recited.

In the present disclosure the term “cured” is often used in connection with the term “matrix material,” particularly when the matrix material includes a polymeric component. In that context the term “cured” should be understood to refer to a chemical process in which one or more liquid reactant components convert to a solid, e.g., via polymerization. In some embodiments when curing results in the formation of a polymer, the polymer may exhibit a degree of polymerization and/or crosslinking that is/are greater than or equal to about 90%, greater than or equal to about 95%, greater than or equal to about 99%, or even about 100%. Thus the term “cured matrix material” should be understood to encompass matrix materials formed by or including a polymeric component that exhibits a degree of polymerization greater than or equal to about 90, 95, 99, or even 100%, a degree of crosslinking of about 90, 95, 99, or even 100%, and combinations thereof. The term “cure time” refers to the amount of time required to convert a matrix precursor to a cured polymeric matrix.

As briefly described in the background, research has suggested that covering the light emitting surface of an LED with a polymer encapsulant having a refractive index greater than that of air can increase the critical angle at the light emitting surface/encapsulant interface (relative to a light emitting surface/air interface), thereby potentially increasing the amount of light extracted from the LED. Although polymeric encapsulants have proven useful in that regard, the polymers used to form such encapsulants often still have a refractive index that is significantly lower than the refractive index of the materials that form the emitting surface of an LED. This can meaningfully limit the improvement in critical angle (and light output) that can be attained with polymeric encapsulants.

Research has also been performed into identifying alternative materials which may be useful as encapsulants for various light sources such as LEDs. In that regard, various composite materials have been developed and investigated for use in lighting applications. Such composites, hereinafter referred to generally as “composite encapsulants” generally include a polymeric matrix material that is loaded with high refractive index (HRI) particles. The polymeric matrix has a refractive index M1, and the HRI particles have a refractive index H1, wherein H1 is greater than M1. As a result, such composite materials may exhibit a composite refractive index, N2, wherein M1<N2<H1.

Although some composite encapsulants have shown promise, the inventors have identified various technical issues that may render them undesirable for certain applications. For example, some composite encapsulant materials include HRI particles that have a particle diameter greater than 30 nanometers (30 nm), and/or which have a tendency to form agglomerates that have an agglomerate size of greater than 30 nm. While such composite encapsulants can increase the amount of light extracted from a light emitting surface of an LED, the inventors have discovered that the relatively large particles/agglomerates therein can result in light scattering within the composite encapsulant. Although such scattering may be relatively small, the inventors have discovered that it can nonetheless contribute to light loss from the device. Indeed in some instances, the inventors discovered that scattering light loss attributable to some composite encapsulants may equal or even exceed the amount of extra light that from a light emitting surface of the light source due to the use of the composite encapsulant.

Moreover, the amount of scattering light loss can increase as the thickness of the encapsulant increases. With that in mind, some composite encapsulants are used in lighting devices in the form of a layer having a thickness of 3 mm or more. At such thicknesses, scattering from the relatively large HRI particles/agglomerates therein can result in a large scattering light loss.

As also briefly explained above, many composite encapsulants were developed for the purpose of improving optical out coupling at an interface defined between the encapsulant and a light emitting surface of a light source. Specifically, such materials were developed to exhibit a composite refractive index (N2) that exceeds the refractive index (M1) of the polymer used as its matrix alone (i.e, M1<N2) thereby increasing the critical angle at the interface with a light emitting surface of a lighting device, e.g., by increasing the ratio of N2/N1 at such interface. While those composite encapsulants have proven useful for improving optical out coupling at a light emitting surface/composite encapsulant interface, the inventors have discovered that the use of composite encapsulants can affect optical performance at other portions of a lighting device.

For example in instances where a lighting device includes a light emitting surface, a composite encapsulant on the light emitting surface, and an optical component (e.g., a lens) on the composite encapsulant, multiple interfaces may be present between various components of the device. For example, such devices may include a first interface defined between the light emitting surface and the composite encapsulant, and a second interface defined between the composite encapsulant and the optical component (e.g., lens). A first critical angle (C1) may therefore be defined at the first interface based on the ratio of the refractive index (N2) of the composite encapsulant to the refractive index (N1) of the light emitting surface, and a second critical angle (C2) may be defined at the second interface based on the ratio of the refractive index of the optical component (N3) to the refractive index of the composite encapsulant (N2). While increasing N2 may increase C1, the inventors have observed that increasing N2 can reduce the ratio of N3/N2 and therefore reduce C2. Therefore while optical coupling may be improved at the first interface, a significant amount of light may be lost in such lighting devices due to total internal reflection at the second interface.

With the foregoing in mind, one aspect of the present disclosure relates to lighting devices that include a composite encapsulant. As will be explained in greater detail below, the lighting devices of the present disclosure generally include a light source (e.g., one or more LEDs) that include a light emitting surface having a first refractive index, N1. A composite encapsulant material having a second refractive index, N2 is disposed directly on the light emitting surface to define a first interface. The composite encapsulant may include a matrix material and HRI particles, such that N2 is defined at least in part by the refractive index (M1) of the matrix material and the refractive index (H1) of the HRI particles. Specifically, in some embodiments the following relationship may be met in the composition encapsulant layers described herein M1 <N2 <H1. In some embodiments, the HRI particles may have a particle and/or agglomerate size of less than or equal to 30 nanometers (nm). For example, in some embodiments the HRI particles may consist or consist essentially of non-agglomerated HRI particles with a particle size less than or equal to 30 nm.

In some embodiments a lens having a third refractive index (N3) is disposed directly on an upper surface of the composite encapsulant to define a second interface. In some or all of those embodiments, the light emitting surface, composite encapsulant, and lens may be configured such that the following refractive index relationships are met:

N1≧N2≧1.6; and

N2≦N3;

where N1 is the refractive index of the light emitting surface of a light source, N2 is a composite refractive index of a composite encapsulant directly on the light emitting surface, and N3 is the refractive index of a lens directly on the composite encapsulant. Moreover, in some embodiments the thickness of the composite encapsulant may be controlled, e.g., to limit or even prevent light losses attributable to scattering. For example, the thickness of the composite encapsulant may range from greater than 0 to about 2 mm, such as from greater than 0 to about 1 mm.

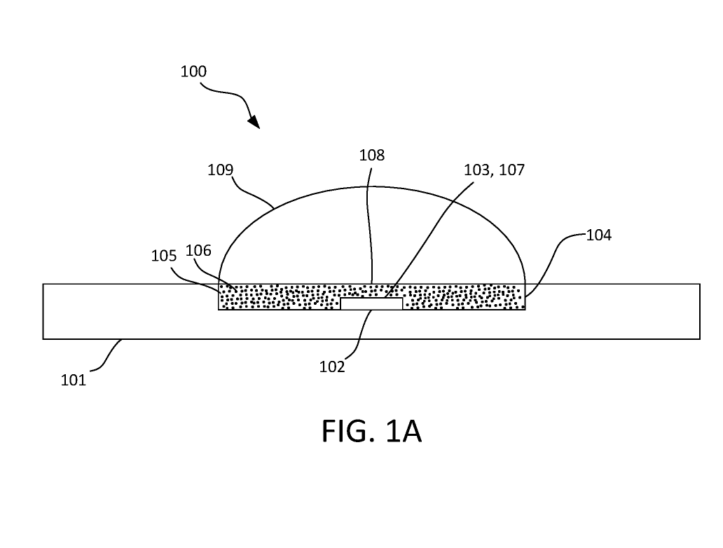

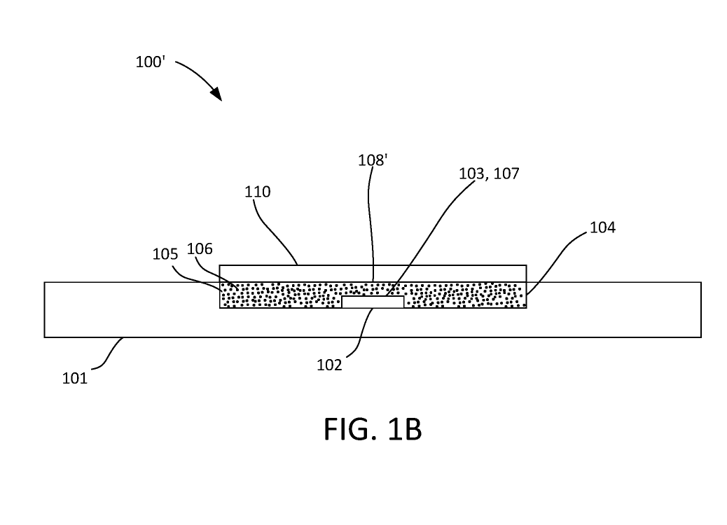

Reference is therefore made to FIG. 1A, which depicts one example of a lighting device consistent with the present disclosure. As shown, FIG. 1A depicts a lighting device 100 that includes support 101, light source 102, composite encapsulant 104, and lens 109. In general, support 101 is configured to provide mechanical support to the various other components of lighting device 100. In that regard support 101 may be any suitable support, such as a circuit board, a frame (e.g., an LED frame), combinations thereof, and the like. In some embodiments support 101 is in the form of or includes a circuit board containing electrical circuits, contacts, etc., for driving light source 102. For example, in instances where light source 102 is an LED (in which case lighting device 100 may be understood to be an LED lighting device such as an LED package), support 101 may be an LED frame that includes circuits and/or contacts for driving an LED. In any case, support 101 may be understood to provide mechanical support for the various components of lighting device 100,

Light source 102 may be any suitable light source that is capable of emitting light from a light emitting surface thereof. Non-limiting examples of suitable light sources that may be used as light source 102 include solid state light sources, such as light emitting diodes. In instances where light source 102 includes one or more LEDs, such LEDs may be configured to emit light from a light emitting surface thereof. Thus for the sake of clarity and illustration, light source 102 is depicted in FIG. 1A as including light emitting surface 103. In the illustrated embodiment, light emitting surface 103 is depicted as being formed on or integral with an upper surface of light source 102, but it should be understood that any suitable side, surface, etc. of light source 102 may be configured as a light emitting surface.

Regardless of its configuration, light source 102 may be configured to produce light, e.g., in response to an electrical signal. For example, light source 102 may be configured to produce light in the ultraviolet, visible, and/or infrared regions of the electromagnetic spectrum. In some embodiments light source 102 is an LED configured to emit light in the ultraviolet, visible, or infrared regions, or some combination thereof. Without limitation, in some embodiments light source 102 is an LED configured to emit light in the visible region. For example, light source 102 may be an LED configured to produce blue, red, yellow, white, or other color light, either directly or through the use of one or more wavelength converters.

In any case as noted above, light source 102 may include a light emitting surface 103. In general, light emitting surface 103 may function to define at least part of a first interface 107 between light source 102 and an environment external to light source 102, such as but not limited to composite encapsulant 104. In that regard, light emitting surface 103 may be formed from any suitable material. For example, light emitting surface 103 may include or be formed from materials having a refractive index (N1) greater than or equal to 1.6. Non-limiting examples of such materials include gallium nitride (GaN—N1˜2.3-2.5) and aluminum gallium indium phosphide (AlGaInP, N1˜3.2-4.5), aluminum gallium nitride (AlGaN), indium gallium nitride (InGaN), cadium zinc selenide (CdZnSe), quantum dot LED materials, organic LED materials, combinations thereof, and the like. Without limitation, in some embodiments light emitting surface 103 is or includes InGaN, AlGaN, or AlGaInP.

As further shown in FIG. 1A, lighting device 100 includes composite encapsulant 104. In general, composite encapsulant 104 generally functions to define at least a part of first interface 107 with light emitting surface 103 of light source 102. Therefore composite encapsulant 104 and light emitting surface 103 may be understood to define first interface 107, wherein the first interface 107 is a light emitting surface/composite encapsulant interface. In that regard, composite encapsulant 104 may be in the form of a layer that is formed on light emitting surface 103. For example, composite encapsulant 104 may be in the form of a layer that is directly on a surface (e.g., upper surface) of light emitting surface 103. In any case, first interface 107 is defined between light emitting surface 103 and composite encapsulant 104. For example in the illustrated embodiment, first interface 107 is defined between an upper surface of light emitting surface 103 and a lower surface of composite encapsulant 104, wherein composite encapsulant 104 is directly on light emitting surface 103.

It is noted that in the illustrated embodiment, light source 102 is shown as being disposed within a cavity (not labeled) formed in support 101, with composite encapsulant 104 filling the portions of the cavity that are not occupied by light source 102, e.g., such that an upper surface of composite encapsulant 104 is substantially coplanar with an upper surface of support 101 in regions proximate to the cavity. Moreover, composite encapsulant 104 is shown as encapsulating light source 102 such that the sides and upper surface of light source 102 are surrounded by composite encapsulant 104. It should be understood that such illustration is for the sake of example only, and that such components may be configured in another manner.

Indeed the present disclosure envisions embodiments wherein support 101, light source 102, composite encapsulant, are configured differently from the embodiment shown in FIG. 1A. For example, in some embodiments support 101 may be configured without a cavity. In such instances, support 101 may have a substantially planar upper surface, wherein one or more light sources 102 disposed on the substantially planar upper surface. Regardless of the configuration of support 101, composite encapsulant 104 need not have the geometry shown in the embodiment of FIG. 1A. For example, in some embodiments composite encapsulant 104 may be configured as a layer that is disposed only directly on an upper surface of light emitting surface 103. Alternatively or additionally, in some embodiments composite encapsulant 104 may be configured such that it is disposed only on a portion (i.e., less than 100%) of light emitting surface 103. Still further, in some embodiments light source 102 is disposed on a substantially planar upper surface of support 101, and composite encapsulant 104 is configured to cover the upper and side surfaces of light source 102, e.g., as generally shown in FIG. 1A but without the recess in support 101.

In any case, composite encapsulant 104 is a composite material that is formed from or includes a matrix material and high refractive index (HRI) particles. This concept is shown in FIG. 1A, which depicts composite encapsulant 104 as including matrix 105 and HRI particles 106. As will be described later the composite encapsulants of the present disclosure may be formed by adding HRI particles to matrix precursor, e.g., to form a mixture, emulsion, dispersion, and/or suspension of the HRI particles and matrix precursor, e.g., in a liquid phase. The mixture, emulsion, dispersion, and/or suspension may then be deposited on a surface (e.g., a light emitting surface) to form an encapsulant precursor. Following such deposition, a curing process may be carried out to cure the encapsulant precursor and form a composite encapsulant.

With the foregoing in mind the present disclosure focuses on embodiments in which a composite encapsulant is formed by a single type of matrix material and a single type of HRI particles. It should be understood that such embodiments are described for the sake of example only, and the composite encapsulants described herein may include more than one type of matrix material, more than one type of HRI particles, and/or additional components other than the matrix material and HRI particles. For example in some embodiments, the composite encapsulants described herein may include at least first and second HRI particles in a polymeric matrix material, wherein the first and second HRI particles differ from one another in composition, average particle/agglomerate size, and/or in some other manner. Without limitation, in some embodiments the composite encapsulants described herein include at last first and second HRI particles that are compositionally different. Alternatively or additionally, in some embodiments the composite encapsulants described herein include at least first and second HRI particles having respective first and second average particle sizes, wherein the first and second particle sizes are different. Still further, in some embodiments the composite encapsulants described herein include first non-agglomerated HRI particles, and second HRI particles which may or may not be non-agglomerated.

As will become apparent from the following disclosure, the matrix material of the composite encapsulants described herein generally serves as a “host” or “binder” material for HRI particles consistent with the present disclosure. In that regard, the matrix material of the composite encapsulants may be formed from or include a wide variety of materials, including inorganic (e.g., ceramic) and organic (e.g., polymeric) materials. Without limitation, in some embodiments the matrix material of the composite encapsulants described herein include are formed from one or polymeric materials. Non-limiting examples of suitable polymeric matrix materials that may be used in the composite encapsulants of the present disclosure include various types of optically transparent polymers, including acrylate polymers such as polymethyl methacrylate, cellulose polymers such as methyl cellulose, ethyl cellulose, etc., epoxide polymers (also known as “epoxy resins”), polyamides, polycarbonates, polyesters such as polyethylene terephthalate, polyimides, polyisobutylenes, polyvinylidene fluoride, polysiloxanes (also known as “silicones”), poly(silphenylene-siloxane) gels (also known as “silphenylenes” or “silarene-siloxanes.”), polystyrenes, and polyvinyl alcohol polymers (PVA). Without limitation, the polymeric matrix material in the composite encapsulants described herein is preferably formed from or includes one or more thermoset polymers, such as one or more epoxides, silicones, polyimides, or a combination thereof.

Alternatively or additionally, one or more luminescent polymers may be used as or in a matrix of a composite encapsulant consistent with the present disclosure. Non-limiting examples of suitable luminescent polymers that may be used in that regard include: (i) Perylene-based polymers such as yellow and red Lumogen® F (BASF) (ii) Conjugated polymer blends such as green emitting poly[{9,9-dioctyl-2,7-divinylenefluorenylene)-alto-co-(2-methoxy-5-(2-ethylhexyloxy)-1,4-phenylene}] (PFPV) and/or red emitting poly[1-methoxy-4-(2-ethylhexyloxy-2,5-phenylenevinylene)] (MEH-PPV); (iii) Composite encapsulated polymer dots (Pdots) such as poly[(9,9-dioctylfluorenyl-2,7-diyl)-alt-co-(1,4-benzo-{2,1′,3}-thiadiazole)] (PFBT), poly(9,9-dio ctylfluorenyl-2,7-diyl) (PFO), poly[2-methoxy-5-(2-ethylhexyloy)-1,4-(1-cyanovinylene phenylene)] (CN-PPV), and/or poly[(9,9-dioctylfluorene)-co-(4,7-di-2-thienyl-2,1,3-benzothiadiazole)] (PF-5DTBT; (iv) DCJTB color conversion layers such as (4-(dicyanomethylene)-2-tert-butyl-6-(1,1,7,7-tetramethyljulolidyl-9-enyl)-4H-pyran); (v) Europium-containing copolymers such as poly[UA-MMA-co-Eu (DBM)2(TOPO)2]; (vi) Polysiloxane or composite encapsulant +fluorescent polymers FABD polymers such as red emitting polymer (9,9-dioctylfluorene (F), anthracene (A), 2,1,3-benzothiadiazole (B) and 4,7-bis(2-thienyl)-2,1,3-benzothiadiazole (D).

The matrix materials of the composite encapsulants described may have a refractive index M1, wherein M1 is less that the composite refractive index (N2) exhibited by the composite encapsulant. M1 may vary considerably depending on the material(s) used as or in the matrix of a composite encapsulant. In some embodiments M1 may range from about 1.3 to less than or equal to about 1.6, such as from about 1.3 to less than 1.6, or even from about 1.3 to about 1.55. Without limitation, in some embodiments M1 ranges from about 1.4 to about 1.6. For example, in some embodiments the matrix of the composite encapsulants described herein is or includes one or more epoxy resins, silicones, and/or polyimides having a refractive index of about 1.4 to less than or equal to 1.6, such as from about 1.5 to less than or equal to 1.6.

The matrix materials for the composite encapsulants described herein may be formed in any suitable manner. For example, the matrix materials described herein may be formed by curing (e.g. polymerizing, crosslinking, etc.) a matrix precursor. The matrix precursor may be any precursor formulation in which HRI particles consistent with the present disclosure can be suspended, mixed, and/or dispersed, and which can be converted to the polymeric matrix material. For example, a matrix precursor may be a formulation of corresponding monomer(s) and optional additional components (e.g., photo initiators, catalysts, crosslinking agents, etc.), which may be converted to the polymeric matrix material by any method known in the art.

In some embodiments the matrix precursors of the present disclosure are selected from thermal and/or photo-polymerizable formulations that exhibit a cure time that varies with applied temperature, light intensity, or a combination thereof. Put in other terms, the cure rate (gel time) of the matrix precursors described herein may be impacted by one or more process parameters applied when such precursors are cured, such as the temperature applied during curing of a thermally curable matrix precursor (curing temperature), the intensity of light (curing light intensity) applied during curing of a photo-polymerizable matrix precursor, or some combination thereof.

For example when the matrix material of a composite encapsulant is a silicone or an epoxy, the matrix precursors thereof may be selected from silicone or epoxy precursors, respectively, wherein such precursors exhibit a cure time that decreases as curing temperature and/or curing light intensity increases, and vice versa. The impact of curing temperature and/or curing light intensity may be evaluated for example by measuring the viscosity of the matrix precursor (and ultimately the resulting polymer) while curing various samples of the matrix precursor under various curing temperatures and/or curing light intensities, and then comparing the measured viscosity vs. time for each sample. Alternatively, curing of the polymer matrix may be evaluated using Fourier transform infrared spectroscopy (FTIR).

The polymeric matrix materials of the present disclosure may also exhibit desirable optical properties such as but not limited to optical transparency with regard to incident light of a given wavelength or wavelength range. For example in some embodiments the polymeric matrix materials transmit greater than or equal to about 80, 85, 90, 95, 99, or even about 100% of incident light in at least one of the ultraviolet, visible, and/or infrared regions of the electromagnetic spectrum. When used in connection with a light emitting diode and HRI particles consistent with the present disclosure, the polymeric matrix material preferably transmits greater than or equal to 80, 85, 90, 95, 99, or even about 100% of incident light emitted by the light emitting diode.

As noted above the composite encapsulants of the present disclosure include one or more types of HRI particles 106 that are distributed within matrix material 105. The HRI particles may be incorporated into the matrix in any suitable manner, and may function at least in part to increase the refractive index of the composite encapsulant, relative to the refractive index of the matrix material alone. For example, the HRI particles may be incorporated into the wavelength converter by adding them to a matrix precursor, after which the matrix precursor may be cured to form the composite encapsulant. In some instances, the combination of HRI particles and matrix precursor may be deposited, e.g., on a light emitting surface of a light source (e.g., light emitting surface 103 of light source 102), after which the matrix may be cured in any suitable manner to form a composite encapsulant including a cured matrix with HRI particles therein.

The HRI particles of the present disclosure may be formed from or include any of a wide variety of materials having a refractive index (H1) in the visible region of the electromagnetic spectrum that is greater than or equal to about 1.6. Non-limiting examples of suitable materials that can be used as HRI particles in the present disclosure include: particles of III-V semiconductors such as GaP (H1˜3.3 at 600 nm), InGaP (H1˜3.7 at 600 nm), GaAs (H1˜3.4 at 600 nm), GaN (H1˜2.4 at 600 nm); particles of II-VI semiconductors such as ZnS (H1˜2.4 at 500 nm), ZnSe (H1˜2.6 at 500 nm), ZnTe (H1˜3.1 at 500 nm), CdS (H1˜2.6 at 500 nm), CdSe (H1˜2.6 at 500 nm), and CdTe (H1˜2.7 at 500 nm); particles of metal oxides such as A1203 (H1˜1.77 at 600 nm), TiO₂ (H1˜2.9 at 500 nm), NiO2 (H1˜2.2 at 500 nm), ZrO₂ (H1n˜2.2 at 500 nm), ZnO (H1˜2.0 at 500 nm) indium tin oxide, chromium oxide, and combinations thereof; particles of yttrium aluminum garnet; particles of diamond (H1˜2.42); particles of high index (H1≧1.6) organic compounds/polymers; combinations, mixtures, and alloys thereof, and the like. Without limitation, in some embodiments the HRI particles include particles of Zirconium Oxide (ZrO₂) particles.

The HRI particles may have any suitable shape. For example, the HRI particles may have a spherical, oblong, platelet, flake, whisker, or other shape, or a combination of such shapes. Without limitation, in some embodiments the HRI particles used herein have a spherical shape. For example, in some embodiments spherical or substantially spherical ZrO₂ particles are used as the HRI particles of the present disclosure. With that in mind, it is noted that the refractive indexes noted above are enumerated for the sake of example to demonstrate the refractive index of particles that are formed from certain materials and which have a certain shape (e.g., spherical, platelet, etc.). One of ordinary skill in the art will understand that the shape of HRI particles may have an impact on their refractive index. With that in mind and as noted above, the HRI particles described herein generally have a refractive index of at least about 1.6.

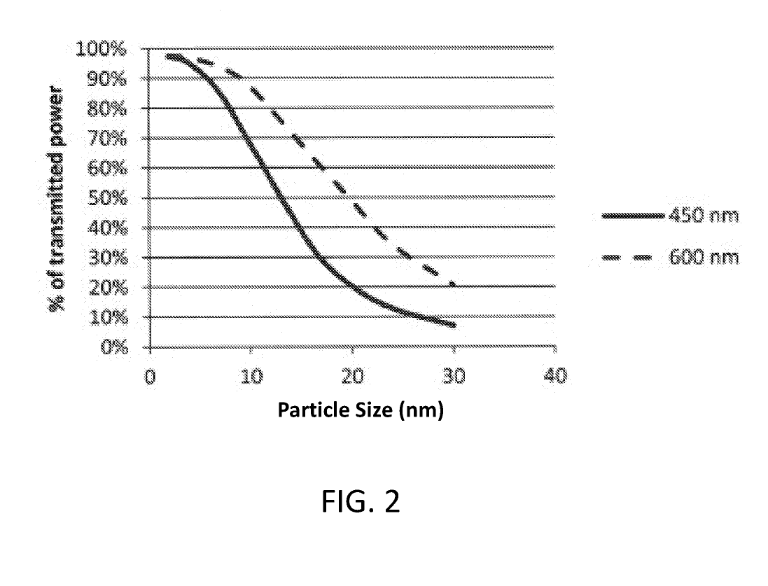

The particle/agglomerate size of the HRI particles may impact the optical properties of the composite encapsulant in which they are included. For example, the particle/agglomerate size of the HRI particles may affect the amount of optical power that is transmitted through a composite encapsulant in which such particles are included. This concept is illustrated in FIG. 2, which a plot of simulated % transmitted power of light vs. particle size, wherein the data was simulated at two different wavelengths based on the use of a hypothetical 1 mm composite encapsulant formed from an epoxy matrix having a refractive index M1 of 1.53 and 30 volume percent of ZrO₂ particles having a refractive index H1 of 2.25, wherein the ZrO₂ particle size was allowed to vary. As shown, the simulations suggest that composite encapsulants that include particles with a particle/agglomerate size less than or equal to about 10 nm are expected to exhibit a low fraction of transmitted light loss (e.g., less than about 20% loss). In contrast, the simulations suggest that composite encapsulants including HRI particles with a particle/agglomerate size greater than 30 nm are expected to exhibit a high fraction of light loss (e.g., greater than about 80%). More generally, the simulated data suggest that the fraction of transmitted light loss through a composite encapsulant consistent with the present disclosure will increase with increasing HRI particle/agglomerate size, and decrease with decreasing HRI particle/agglomerate size. While not wishing to be bound by theory, it is believed that the loss in transmitted power is attributable to scattering loss introduced by the inclusion of relatively large particles/agglomerates.

It may therefore be desirable to select HRI particles for use in the composite encapsulants described herein based at least in part on their particle size. Therefore in some embodiments the composite encapsulants described herein may include HRI particles with an average particle size ranging from greater than 0 to less than about 30 nm, such as from about 1 to about 25 nm, about 1 to about 15 nm, or even about 1 to about 10 nm. In some embodiments, the HRI particles have an average particle diameter of less than about 10 nm, and are formed from one or more of the above noted materials. It is noted that the term “particle size” as used herein refers to the largest linear dimension of a single HRI particle. Therefore in instances where the HRI particles are spherical, such particles should be understood to have a particle size equal to their diameter. Alternatively where the HRI particles are flakes, whiskers, etc., the particle size of such particles should be understood to be their largest linear dimension.

As may also be appreciated, the relatively small particle size of the HRI particles described herein may present processing and/or other challenges. For example, as the size of the HRI particles, the particles may tend to group together to form agglomerates, wherein the agglomerates are of a size that is larger (e.g., several times larger) than individual particles of the wavelength conversion material. As such agglomerates may exhibit optical and/or other properties that differ from the properties of individual (i.e., non-agglomerated) HRI particles, it may be desirable to take steps to limit and/or prevent agglomeration of the HRI particles used in the context of the present disclosure. For example and as noted above, it may be desirable to coat or otherwise treat the HRI particles with one or more organic or inorganic ligands to limit and/or prevent their agglomeration, facilitate dispersion, etc. For example, in some embodiments ZrO₂ particles having an average particle size within the above noted ranges are used, wherein such particles are functionalized with one or more reactive or inert ligands (e.g., vinyl, epoxy, etc.) that may function to limit or prevent agglomeration. Of course, such treatment may not be necessary in all instances, such as when HRI particles that do not tend to agglomerate are used. With that in mind, to the extent the composite encapsulants described herein may include agglomerates, the size of such agglomerates may be less than about 30 nm, such as from about 1 to less than 30 nm, about 1 to about 20 nm, about 1 to about 15 nm, or even from about 1 to about 10 nm. Without limitation, in some embodiments the composite encapsulants described herein only include non-agglomerated HRI particles.

As noted above the composite encapsulants may exhibit a composite refractive index, N2, wherein N2 is at least partly defined by the refractive index (M1) of the matrix material and the refractive index (H1) of the HRI particles used therein. For example, N2 may be a weighted average of H1 and M1 that takes into account the relative amount of HRI particles and matrix material in a composite encapsulant. In any case, N2 may range, for example, from greater than or equal to about 1.6 to about 2.4, such as from about 1.6 to about 2.0, about 1.6 to about 1.8, or even about 1.6 to about 1.7, e.g., at 450 nm or 600 nm. In some embodiments, N2 is about 1.6 to about 1.7 at 450 nm or 600 nm.

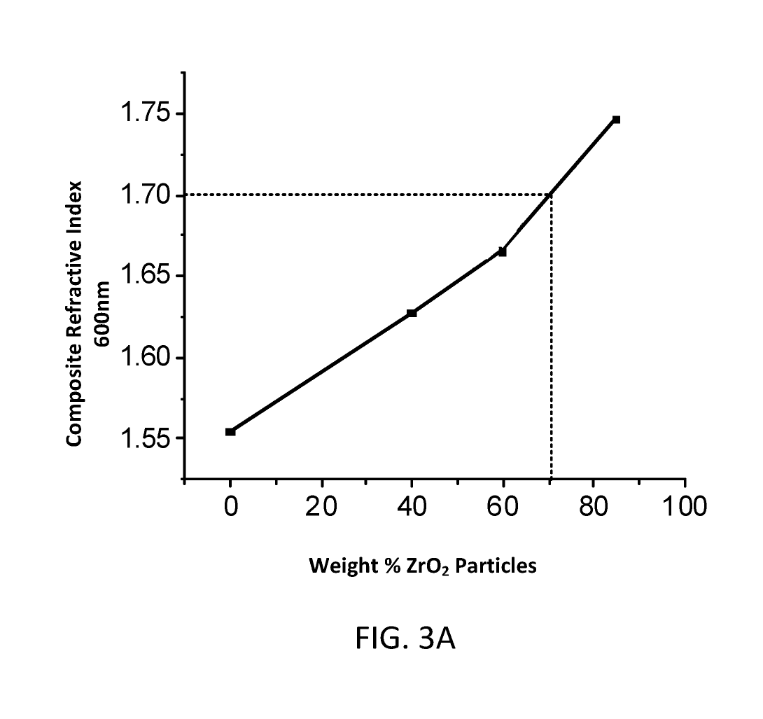

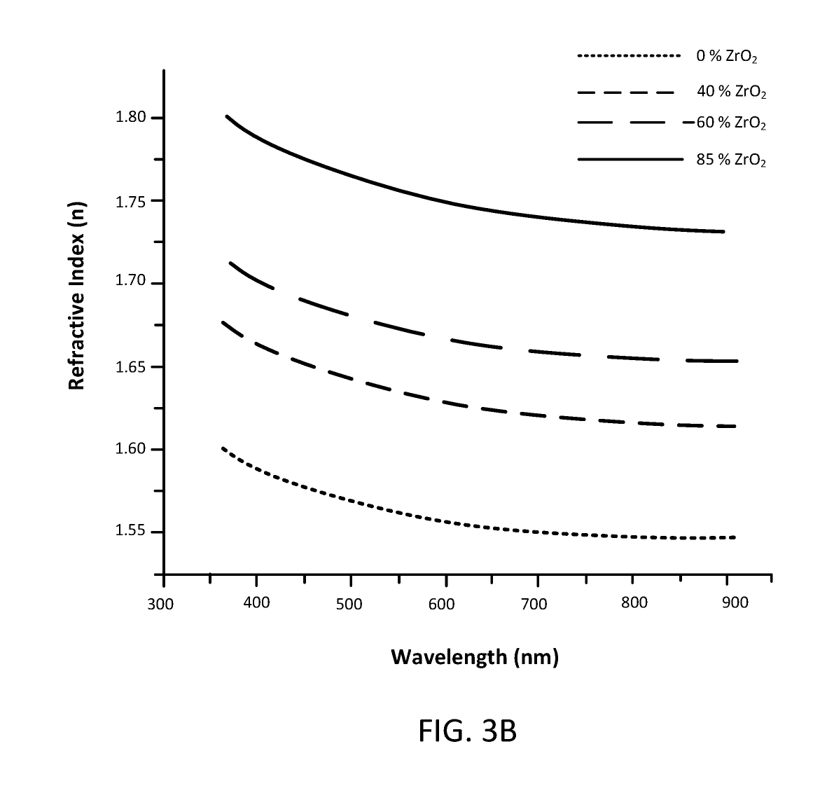

In many instances the refractive index H1 of the HRI particles is higher than the refractive index M1 of a matrix material in a composite encapsulant. It may therefore be appreciated that the amount of HRI particles in the matrix material may impact the optical properties of a composite encapsulant, and in particular the refractive index of a composite encapsulant. More particularly, increasing the amount of HRI particles relative to the amount of matrix will generally result in an increase in composite refractive index N2, until N2 approaches the bulk refractive index of the material used to form the HRI particles. This concept is illustrated in FIG. 3A, which is a plot of the refractive index of various example composite encapsulants consistent with the present disclosure, which are described later in connection with Examples 1-3. In general, the example composite encapsulants included an epoxy matrix having a refractive index (M1) of 1.53 and varying amounts of ZrO₂ particles with a refractive index H1 of about 1.8. As shown, in the absence of particles the refractive index of the matrix material was about 1.53. In contrast, the composite refractive index for the composite encapsulants containing 40%, 70%, and 85 weight % ZrO₂ particles was about 1.625, about 1.7, and about 1.75, respectively. With that in mind, FIG. 3B depicts composite refractive indices for the same composite encapsulants measured by an ellipsometer over various wavelengths, and demonstrates that the trends shown in FIG. 3A are expected regardless of wavelength.

It may therefore be desirable to control the amount of HRI particles in a composite encapsulant to attain desired optical properties, and in particular a desired composite refractive index. With that in mind the amount of HRI particles in the composite encapsulants described herein may vary widely. In some embodiments, the HRI particles may be present in the composite encapsulants described herein in an amount ranging from about 1 to about 90 weight %, such as about 10 to about 85 weight %, about 20 to about 70 weight%, or even about 30 to about 60 weight %, relative to the total weight of the composite encapsulant. In some embodiments, the amount of HRI particles in the composite encapsulant ranges from about 50 to about 80 weight %, such as about 70% by weight. Put in other terms, the volume of HRI particles in the matrix may range from greater than 0 to about 55 volume %, such as from about 12 to about 53 volume %, or even about 15 to 25 volume %. In some instances, the composite encapsulants described herein include a polyimide, silicone, or epoxy matrix containing about 60 to about 80% ZrO₂ particles, wherein the ZrO₂ particles are non-agglomerated and the composite encapsulant exhibits a composite refractive index, N2, of about 1.6 to about 1.8.

As noted above it is believed that the use of HRI particles may cause incident light (e.g., from light source 102) to scatter. This is particularly true in instances where larger HRI particles are used, though scattering may result from the use of relatively small particles (e.g., particle size from greater than 0 to about 30 nm) as well. Although scattering resulting from the use of HRI particles within the above noted particle/agglomerate size ranges is believed to be small, such scattering can increase the length of the light path and thereby result in light loss. Such loss can potentially be significant, particularly if the light path through a composite encapsulant is relatively long.

Therefore independently or in addition to controlling the particle size of HRI particles and/or the composite refractive index, it may also be desirable to control the thickness of a composite encapsulant to limit and/or minimize the length of the light path there-through. With that in mind, the thickness of the composite encapsulants described herein may vary widely, and composite encapsulants having any suitable thickness may be used. For example, the thickness of the composite encapsulants described herein may be greater than 0 to less than about 3 millimeters (mm), such as from greater than 0 to about 1 mm, from greater than 0 to about 0.75 mm, from greater than 0 to about 0.5 mm, from greater than 0 to about 0.25 mm, or even from greater than 0 to about 0.1 mm. Without limitation, in some embodiments the composite encapsulants used herein are in the form of a layer on a light emitting surface, wherein the layer has a thickness within the one or more of the above mentioned ranges. For example, in some embodiments such a layer may have a thickness ranging from about 0.05 to about 2 mm. Returning to FIG. 1A, as described above composite encapsulant 104 may be formed directly on the light emitting surface 103 of light source 102. In such instances, a first interface 107 may be defined between light emitting surface 102 and composite encapsulant 104, wherein a first critical angle is defined at the first interface 103. In particular, the first critical angle may be defined at least in part by the ratio of the composite refractive index, N2, of composite encapsulant 104 to the first refractive index, N1, of the light emitting surface, i.e., N2/N1. More particularly, the first critical angle may increase as the ratio of N2/N1 increases, and vice versa. As the first critical angle may directly impact the degree of optical outcoupling from light emitting surface 103 into composite encapsulant 104, it may be desirable to select the materials and configuration of light emitting surface 102 and composite encapsulant 104 so as to increase the ratio of N2/N1, thereby increasing the first critical angle defined at first interface 107 and increasing the degree of optical outcoupling between light emitting surface 103 and composite encapsulant 104. For example, in some embodiments it may be desirable to configure composite encapsulant 104 and light emitting surface 103 such that N2 is greater than or equal to about 60% of N1, such as from greater than or equal to about 66% of N1, greater than or equal to about 70% of N1, greater than or equal to about 80% of N1, or even greater than or equal to about 90% of N1. Without limitation, in some embodiments N2 is greater than or equal to about 66% of N1, and ranges from about 1.65 to about 1.8.

Again returning to FIG. 1A, as described above light source 100 may further include a lens 109 or other optical component (not shown) that is disposed directly on a surface of composite encapsulant 104. In instances where lens 109 is used, it may be any suitable lens that is capable of redirecting light transmitted through composite encapsulant 104. For example and as shown in FIG. 1A, lens 109 may in the form of a hemispherical (e.g., dome-shaped) lens, though other lens configurations may of course be used and are contemplated by the present disclosure. For example, lens 109 in some embodiments may be in the form of a substantially flat layer. Alternatively or additionally, in some embodiments lens 109 may be include one or more concave and/or convex recesses, facets, or other geometric structures, which may be formed in an upper or a lower surface thereof

It is noted that in the embodiment of FIG. 1A, lens 109 is depicted as being formed directly on and covering the entirety of the upper surface of composite encapsulant 104. It should be understood that such illustration is for the sake of example only, and that lens 109 may be configured in a different manner. For example, in some embodiments lens 109 may be disposed over only a portion of a surface of composite encapsulant 104. Alternatively or additionally, one or more additional layers (e.g., wavelength conversion layers) may be present between lens 109 and composite encapsulant 109.

Regardless of its configuration, lens 109 may be configured to alter the direction of light transmitted through composite encapsulant 104. In that regard, it may be understood that lens 109 may have a refractive index, N3, wherein N3 is greater than, less than, or equal to the refractive index N2 of composite encapsulant 104. Without limitation, in some embodiments the refractive index N3 of lens 109 is greater than or equal to the composite refractive index, N2, of composite encapsulant 104. With that in mind, lens 109 may be formed from or include a wide variety of materials, and may exhibit any suitable refractive index. Non-limiting examples of suitable materials that may be used to form lens 109 include optically transparent materials such as optical polymers (e.g., polyacrylates, polycarbonates, etc. with N3<1.6); SiC (N3˜2.7 at 500 nm), aluminum oxide (e.g., sapphire; N3˜1.8 at 500 nm), diamond (N3˜2.4 at 500 nm), high index glass (N3˜1.7-2.0), combinations thereof, and the like. Without limitation, in some embodiments lens 109 is formed from or includes a material with a refractive index of about 1.8 or more, such as aluminum oxide (sapphire).

Lens 109 in some embodiments is formed directly on composite encapsulant 104. In such instances, a second interface 108 may be defined between composite encapsulant 104 and lens 109, wherein a second critical angle is defined at the second interface 108. In particular, the second critical angle may be defined at least in part by the ratio of the refractive index, N3 of lens 109 to the composite refractive index, N2, of composite encapsulant 104, i.e., N3/N2. More particularly, the second critical angle may increase as the ratio of N3/N2 increases, and vice versa. As the second critical angle may directly impact the degree of optical outcoupling from composite encapsulant 104 into lens 109, it may be desirable to select the materials and configuration of composite encapsulant 104 and lens 109 so as to increase the ratio of N3/N2, thereby increasing the second critical angle defined at second interface 108 and increasing the degree of optical outcoupling between composite encapsulant 104 and lens 109.

As noted above optical elements other than or in addition to a lens may be used on composite encapsulant 104. For example, in some embodiments one or more wavelength converters may be disposed directly on an upper surface of composite encapsulant 104. In general, such wavelength converters may function to convert light (primary light) transmitted through composite encapsulant 104 into secondary light, e.g., via phosphorescence or fluorescence. Various compositions for wavelength converters are well understood in the lighting industry, and therefore is not reiterated here. In general, any wavelength converter suitable for use with an LED may be used as a wavelength converter in the context of the present disclosure.

In that regard reference is made to FIG. 1B, which depicts one example of a lighting device 100′ including a wavelength converter consistent with the present disclosure. As shown, lighting device 100′ includes many of the same components as lighting device 100. Therefore in the interest of brevity such components are not described again. In addition, lighting device 100 include wavelength converter 110, which in this instance is formed directly on the upper surface of composite encapsulant 104, so as to define a second interface 108′. In that regard, it is noted that wavelength converter 110 may have an refractive index (N3) that is within the range(s) specified above for lens 109. Moreover, the refractive index (N3) of wavelength converter 110 may bear the same relationship to the refractive index of other materials (e.g., of composite encapsulant 104) as the refractive index of lens 109 discussed above.

For the sake of simplicity and ease of understanding, wavelength converter 110 is depicted in FIG. 1B as a substantially flat layer. It should be understood that such geometry is depicted for the sake of example only, and the wavelength converter 110 may have any suitable geometry. For example in some embodiments wavelength converter may be in the shape of a dome, a concave or convex lens, combinations thereof, and the like.

Moreover, it is noted that FIGS. 1A and 1B depict the use of lens 109 and wavelength converter 110 in isolation. It should be understood that such illustrations are for the sake of example, and that in some embodiments lens 109 and wavelength converter 110 may be used in combination. For example, in some embodiments the lighting devices described herein include a wavelength converter 110 directly on composite encapsulant 104, and a lens 109 directly on wavelength converter 110.

In some embodiments, it may be desirable to select the materials and/or configuration of light emitting surface 103, composite encapsulant 104, and lens 109 so as to achieve a desired balance of optical properties at first and second interfaces 107, 108. Thus for example, in some embodiments light source 102, composite encapsulant 104, and lens 109/wavelength converter 110 may be configured to exhibit refractive indexes N1, N2, and N3, respectively, wherein such indexes are within the above mentioned ranges, and the following relationships are met:

N1≧N2≧1.6; and

N2<N3.

As one non-limiting example of a configuration that may meet the above relationships, mention is made of a lighting device that includes an LED with a light emitting surface formed GaN (N1˜2.3-2.5), AlGaN (N1˜2.3-2.5, or AlGaInP (N1˜3.2-4.5), a composite encapsulant having a second refractive index of about 1.8 formed from an epoxy, polyimide, or silicone matrix (M1˜1.5) and about 30 volume % of (e.g., non-agglomerated) zirconium oxide particles (H1˜2.25) with a particle/aggregate diameter of less than about 30 nm (e.g., about 1 to about 10 nm), and a sapphire lens (N3˜1.8). Of course, other configurations are possible and are envisioned by the present disclosure.

In some embodiments the lighting devices described herein may exhibit an improvement in optical power, relative to lighting devices that do not include a composite encapsulant consistent with the present disclosure. For example, lighting devices that include a composite encapsulant consistent with the present disclosure may exhibit greater than or equal to about 10%, about 15%, or even about 20% higher light output (or more), relative to lighting devices that do not include a composite encapsulant consistent with the present disclosure. As evidence of such improvement, reference is made to the examples described in detail later.

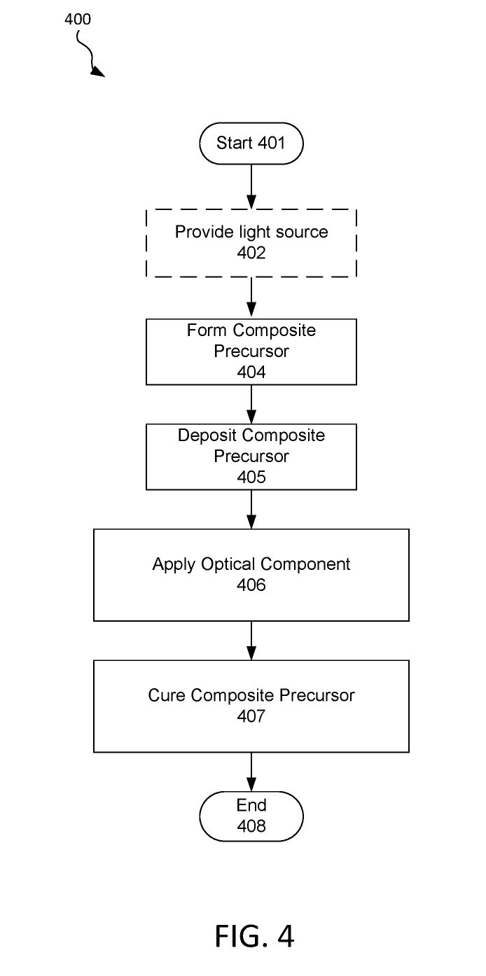

Another aspect of the present disclosure relates to methods of making lighting devices including a composite encapsulant and a lens consistent with the present disclosure. In that regard reference is made to FIG. 4, which is a flow chart of example operations consistent with one embodiment of a method of making a lighting device consistent with the present disclosure. For the sake of clarity and ease of understanding, FIG. 4 depicts a method in which a composite encapsulant is formed by depositing a composite precursor on a light emitting surface of a light source, after which an optical element such as a lens, a wavelength converter, or the like. Subsequently, the composite precursor is cured to form a solid material adhered to both light emitting surface and the lens/wavelength conversion layer. It should be understood that such a method is described for the sake of example only, and that the lighting devices described herein may be formed by other methods.

The method 400 of FIG. 4 begins at block 401. The method may then proceed to optional block 402, pursuant to which a light source such as an LED may be provided. Operations pursuant to block 402 may be understood to include operations to form a light source having a light emitting surface, such as light emitting diode. As such operations are generally well understood in the art, they are not described herein. In any case, it should be understood that method 400 need not include the operations of block 402, as light sources including a light emitting surface (e.g., LEDs) may be purchased commercially or prepared well in advance of the other operations of method 400. Block 402 is therefore illustrated with hashing to illustrate it optional nature. In any case, the light source(s) may be provided on a support, such as support 101 of FIGS. 1A and 1B described above.

Following the operations of block 402 (or if such operations are not required), the method may proceed to block 404. Pursuant to block 402, a composite precursor may be provided on (e.g., directly on) the light emitting surface of a light source. Formation of such a precursor may be accomplished in any suitable manner. For example, in some embodiments formation of a composite precursor may include the addition of HRI particles to a precursor of a matrix material to be used in the composite encapsulant. For example, where a polymer is to be used as a matrix material for a composite encapsulant, formation of a composite precursor may involve addition of HRI particles to a precursor (e.g., monomers, reactants, etc.) of the matrix material. The amount of HRI particles added to the precursor may depend on various considerations, such as the miscibility of the particles in the precursor materials, the amount of HRI particles desired in the composite encapsulant, etc. In instances where a matrix material of a composite encapsulant is formed by the reaction of multiple precursor components (e.g., in a two part epoxy), HRI particles may be added in the same or different amounts to each precursor component, after which the precursor components may be combined.

To facilitate the introduction of HRI particles into a matrix precursor, it may be advantageous to form a mixture, colloid, emulsion, and/or dispersion of HRI particles and a matrix precursor in a liquid phase. Any suitable liquid phase for forming such a mixture, colloid, emulsion, and/or dispersion may be used, depending on the nature of the matrix precursor and/or the HRI particles. Non-limiting examples of suitable liquid phases include polar and non-polar organic solvents, such as but not limited to aromatic solvents such as benzene, toluene, xylene, etc., ketones such as acetone, methyl ethyl ketone, methyl isobutyl ketone, etc., halogenated solvents such as chloroform, chlorobenzene, dichloromethane, etc., alcohols such as methanol, ethanol, propanol, etc., combinations thereof, and the like. Without limitation, in some embodiments formation of a composite precursor involves forming a mixture, colloid, dispersion, or emulsion of HRI particles and one or more matrix precursors in a liquid phase such as toluene or another polar or non-polar solvent.

In any case, the operations of block 404 may result in the formation of a composite precursor. As used herein, the term “composite precursor” may be understood to refer to a precursor of a composite encapsulant, which may be processed to form a composite encapsulant consistent with the present disclosure. Such processing may include, for example, curing or otherwise polymerizing the matrix precursor materials included in the composite precursor, e.g., by the application light, heat, or in some other manner. In instances where the matrix precursor and HRI particles are included in a liquid phase as described above, such processing may also include executing a drying process to remove the liquid phase.

Once a composite precursor has been prepared, method 400 may proceed from block 404 to block 405. Pursuant to block 405, the composite precursor prepared pursuant to block 404 may be deposited, e.g., on a light emitting surface of a light source, on substrate or other support, and/or in a mold. Without limitation, in some embodiments the composite precursor is deposited on (e.g., directly on) a light emitting surface of a light source such as a light emitting diode. Such deposition may be accomplished in any suitable manner, depending on the physical and chemical properties of the matrix precursor and/or the HIR particles contained therein. For example, in some embodiments that matrix precursor may be deposited on a light emitting surface or another support via drop-casting, spin-coating, ink-jet printing, spraying, transfer printing, vacuum deposition, electrohydrodynamic jet printing, micro contact printing, nanoimprint lithography, combinations thereof, and the like. For example, in instances where composite precursor includes a liquid phase containing HRI particles and a matrix precursor, the composite precursor (in this case, HRI particles and matrix precursor in a liquid phase) may be deposited on a light emitting or other surface.

Following deposition of the composite precursor, method 400 may advance from block 405 to block 406, pursuant to which an optical component such as a lens and/or wavelength converter may be provided on (e.g., directly on) a surface of the composite encapsulant. In instances where the optical component is formed from a polymeric material, it may be formed by depositing the polymeric material or a precursor thereof on a surface of the composite encapsulant, e.g., by spin coating, ink-jet printing, or the like. Alternatively, an optical component such as a lens may be formed separately, and then placed on the top of the composite precursor In the latter case, coupling of an optical component to a composite precursor may be accomplished using so-called “pick and place” technology, wherein an optical component may be picked up by a placement arm, appropriately positioned on a surface of a composite precursor.

Once the optical component is applied to the composite precursor, method 400 may proceed from block 406 to block 407, pursuant to which the composite precursor is cured to produce a solid composite encapsulant. Following curing, the resulting solid composite encapsulant may be physically or chemically bonded to the light emitting surface of the light source, as well as physically or chemically bonded to the lower surface of the optical component. It may therefore be understood that in such instances, the cured composite encapsulant is acting as an adhesive to couple the optical component to the light emitting surface of the light source.

### EXAMPLES

For the sake of illustration the present disclosure will now proceed to describe several examples in which a combination of wavelength converting particles are used to form a single layer wavelength converter consistent with the present disclosure. It should be understood that the following examples are representative only, and should not be considered to represent then entire scope of the invention described herein.

### Examples 1-3

To investigate optical performance and other properties various composite encapsulants consistent with the present disclosure were formed. To form the example composite encapsulants, a dispersion of organically modified ZrO₂ particles having a particle size ranging from about 2 to about 5 nanometers was purchased from a commercial source. The dispersion contained 50 parts ZrO₂ particles and 50 parts of a liquid phase (toluene) by weight. A two-part epoxy formed from a 1:1 ratio of resin (part A) and curing agent (part B) was selected as a matrix for the composite encapsulant.

100 parts of the dispersion of ZrO₂ particles was mixed with X parts of part A (resin), wherein X was equal to 75, 33.3, and 8.8 for three different samples. The resulting part A mixtures were then exposed to a vacuum at 60° C. to remove the liquid phase. The resulting mixture included 40, 60, and 85% by mass of ZrO₂ in the part A resin. The same procedure was repeated for the part B, so as to obtain a mixture of part B curing agent containing 40, 60, and 85% by mass of ZrO₂ particles. The mixtures of Part A and B containing ZrO₂ particles were then combined in a 1:1 ratio. The resulting combinations were then deposited on glass sides in the form of a layer having a thickness ranging from about 50 to about 100 microns (μm). The layers were then cured at 130° C. for two hours, resulting in the production of optically transparent composite encapsulants formed from an epoxy matrix including 40, 60, and 80% by weight of high refractive index ZrO₂ particles. As a reference, an encapsulant layer of the same epoxy and thickness was formed in the same way on a glass slide, but did not include any HRI particles.

The refractive index of the coatings was measured using a J A Woollam M-200 Ellipsometer at 450 nm and 600 nm. The results are reported in table 1 below.

TABLE 1
Refractive Index of Example Composite Encapsulants

| | | | Refractive | Refractive |
|---|---|---|---|---|
| | Weight % ZrO₂ | Volume % ZrO₂ | index | Index |
| Example | in Epoxy | in Epoxy | at 450 nm | at 600 nm |
| Reference | 0 | 0 | 1.57 | 1.55 |
| Example 1 | 40 | 12 | 1.65 | 1.62 |
| Example 2 | 60 | 23 | 1.68 | 1.67 |
| Example 3 | 85 | 53 | 1.76 | 1.75 |

### Example 4

To evaluate performance in a lighting device, multiple lighting devices including a composite encapsulant consistent with the present disclosure were prepared. In each case, the composite encapsulant included 70 weight % ZrO₂ particles and had a refractive index of 1.7. The formation of the composite encapsulants used in this example was the same as discussed above for examples 1-3, except that the amount of particles including the two part epoxy was adjusted as needed to achieve a composite encapsulant containing 70% by weight of such particles. The composite encapsulants were formed as a layer directly on a light emitting surface of a 1 mm² LED die that was mounted on a test printed circuit board and a ceramic lead frame for easy handling. The LED die was configured to emit light in the red portion of the visible region electromagnetic spectrum (620 nm). A half ball sapphire lens with a base diameter of 6 mm was glued to the surface of the composite encapsulant, and the assembly was cured at 120° Celsius for 2 hours. As reference samples, several reference lighting devices were prepared in the same manner as the example lighting devices, except insofar as they did not include any ZrO₂ or other HRI particles in the encapsulant. As a result, the reference lighting devices included an encapsulant with a refractive index of 1.53.

Photometry was then conducted on the example lighting devices and the reference lighting devices to determine the optical power downstream of the lens. Specifically, each sample was placed into an integrating sphere with the diameter of 1.0 m, equipped with the spectrophotometer. Each sample was powered with a DC current of 300 mA. The optical power and emission spectrum of each sample was measured using the spectrophotometer. Luminous output was calculated using these data according to ISO 23539:2005(E)/CIE 010/E (2004). The testing revealed that the example lighting devices exhibited an average optical power of about 220 milliwatts (mW). In contrast, the reference lighting devices exhibited an average optical power of about 182 mW. Put in other terms, the average optical power of the example lighting devices was about 21% higher than the average optical power of the reference lighting devices. Likewise, the luminous output from the example lighting devices was measured to be on average 61 lumens (lm) per device, compared to an average of 51 lm produced by reference lighting devices. That is, the luminous output of the samples was about 20% higher than the reference samples.

Other than in the examples, or where otherwise indicated, all numbers expressing endpoints of ranges, and so forth used in the specification and claims are to be understood as being modified in all instances by the term “about.” Accordingly, unless indicated to the contrary, the numerical parameters set forth in the specification and attached claims are approximations that may vary depending upon the desired properties sought to be obtained by the present disclosure. At the very least, and not as an attempt to limit the application of the doctrine of equivalents to the scope of the claims, each numerical parameter should be construed in light of the number of significant digits and ordinary rounding approaches.

Notwithstanding that the numerical ranges and parameters setting forth the broad scope of the present disclosure are approximations, unless otherwise indicated the numerical values set forth in the specific examples are reported as precisely as possible. Any numerical value, however, inherently contains certain errors necessarily resulting from the standard deviation found in their respective testing measurements.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A lighting device comprising:
a light source comprising a light emitting surface with a first refractive index, N1;
a composite encapsulant having an upper surface and a lower surface that is directly on the light emitting surface, the composite encapsulant having a second refractive index, N2, and comprising a matrix and non-agglomerated high refractive index particles; and
an optical component directly on the upper surface of the composite encapsulant, the optical component having a third refractive index N3;
wherein the following relationships are met:
N1>N2>1.6; and
N2<N3.

2. The lighting device of claim 1, wherein said light source comprises at least one light emitting diode.

3. The lighting device of claim 1, wherein:
said second refractive index is a composite refractive index at least partially defined by a refractive index, M1, of said matrix material and a refractive index, H1, of said high refractive index particles; and
H1>M1.

4. The lighting device of claim 2, wherein the lower surface of said composite encapsulant is physically or chemically bonded to the light emitting surface, and the upper surface of said composite encapsulant is physically or chemically bonded to said optical component.

5. The lighting device of claim 4, wherein said optical component is a wavelength converter, a lens, or a combination thereof.

6. The lighting device of claim 4, wherein said non-agglomerated high refractive index particles have an average particle size less than 30 nm.

7. The lighting device of claim 6, wherein said non-agglomerated high refractive index particles have an average particle size less than 10 nanometers (nm).

8. The lighting device of claim 6, wherein said non-agglomerated high refractive index particles are formed from a high refractive index material selected from the group consisting of: GaP, InGaP, GaAs, GaN; ZnS, ZnSe, ZnTe, CdS, CdSe, CdTe, Al2O3, TiO2, NiO2, ZrO_{2,} ZnO, indium tin oxide, chromium oxide, yttrium aluminum garnet, diamond, organic compounds having a refractive index >1.6, combinations, mixtures, and alloys thereof.

9. The lighting device of claim 8, wherein said non-agglomerated high refractive index particles comprise ZrO₂ particles with an average particle size of less than about 10 nanometers (nm).

10. The lighting device of claim 4, wherein said composite encapsulant has a thickness that is less than about 1 mm.

11. The lighting device of claim 1, wherein said matrix comprises one or more of an epoxy resin, a polysiloxane, or a polyimide.

12. The lighting device of claim 4, wherein:
said matrix comprises one or more of an epoxy resin, a polysiloxane, or a polyimide;
said non-agglomerated high refractive index particles comprise ZrO₂ particles with an average particle size of less than about 10 nanometers (nm);
said composite encapsulant has a thickness less than about 1 mm; and
said optical component is a lens.

13. A method of making a lighting device, comprising:
forming a composite precursor directly on a light emitting surface of a light source;
applying an optical component to the composite precursor; and
curing the composite precursor to form a composite encapsulant; wherein:
the light emitting surface has a first refractive index, N1;
the composite encapsulant has a second refractive index, N2, and comprises a matrix and non-agglomerated high refractive index particles;
the optical component is directly on the composite encapsulant and has a third refractive index, N3; and
the following relationships are met:
N1>N2>1.6; and
N2<N3.

14. The method of claim 13, wherein said light source comprises at least one light emitting diode.

15. The method of claim 13, wherein:
said second refractive index is a composite refractive index at least partially defined by a refractive index, M1, of said matrix material and a refractive index, H1, of said high refractive index particles; and
H1>M1.

16. The method of claim 14, wherein the lower surface of said composite encapsulant is physically or chemically bonded to the light emitting surface, and the upper surface of said composite encapsulant is physically or chemically bonded to said optical component.

17. The method of claim 16, wherein said optical component is a wavelength converter, a lens, or a combination thereof.

18. The method of claim 16, wherein said non-agglomerated high refractive index particles have an average particle size less than 30 nm.

19. The method of claim 18, wherein said non-agglomerated high refractive index particles are formed from a high refractive index material selected from the group consisting of: GaP, InGaP, GaAs, GaN; ZnS, ZnSe, ZnTe, CdS, CdSe, CdTe, Al2O3, TiO2, NiO2, ZrO_{2,} ZnO, indium tin oxide, chromium oxide, yttrium aluminum garnet, diamond, organic compounds having a refractive index >1.6, combinations, mixtures, and alloys thereof.

20. The light source of claim 16, wherein:
said matrix comprises one or more of an epoxy resin, a polysiloxane, or a polyimide;
said non-agglomerated high refractive index particles comprise ZrO₂ particles with an average particle size of less than about 10 nanometers (nm);
said composite encapsulant has a thickness less than about 1 mm; and
said optical component is a lens.
